(19) United States
(12) Patent Application Publication
(10) Pub. No.: US 2025/0081524 A1
(43) Pub. Date: Mar. 6, 2025

(54) SEMICONDUCTOR DEVICE AND METHOD FOR MANUFACTURING THE SAME

(71) Applicants: BEIJING SUPERSTRING ACADEMY OF MEMORY TECHNOLOGY, Beijing (CN); INSTITUTE OF MICROELECTRONICS, CHINESE ACADEMY OF SCIENCES, Beijing (CN)

(72) Inventors: Ziyi LIU, Beijing (CN); Huilong ZHU, Beijing (CN)

(21) Appl. No.: 18/260,320

(22) PCT Filed: Dec. 24, 2021
(86) PCT No.: PCT/CN2021/141028

§ 371 Date: Jul. 4, 2023

(30) Foreign Application Priority Data
Dec. 14, 2021 (CN) 202111529029.5

(51) Int. Cl. H01L 29/417; H01L 29/66; H01L 29/786

(52) U.S. Cl. CPC H10D 30/6729; H10D 30/031; H10D 30/6728; H10D 64/017; H10D 64/018; H10D 64/252

(57) ABSTRACT

A semiconductor device and a method for manufacturing the same. A substrate is provided. A first source-drain layer, a channel layer, and a second source-drain layer are sequentially stacked on the substrate. Both a gate dielectric layer and a gate structure surround the channel layer laterally. The gate structure includes a first portion extending laterally and a second portion extending upward from a periphery of the first portion. A second portion is located at a periphery of the second source-drain layer. A spacer layer is formed at an outer sidewall of the gate structure. The gate structure is etched to reduce a thickness of the gate structure. A sacrificial structure covering the gate structure is formed, and a capping layer covering the second source-drain layer, the sacrificial structure, and the spacer layer is formed. Thereby, the sacrificial structure is located at the periphery of the second source-drain layer and enclosed by the spacer layer. The capping layer is etched to obtain a first contact hole reaching the sacrificial structure. The sacrificial structure at the bottom of the first contact hole is removed to form a gap under the first contact hole. A first contact structure is formed in the first contact hole and the gap. Self-alignment between a bottom of the first contact structure and the gate structure is achieved, and the device has higher reliability.

This application is the national phase of International Application No. PCT/CN2021/141028, titled “SEMICONDUCTOR DEVICE AND METHOD FOR MANUFACTURING THE SAME”, filed on Dec. 24, 2021, which claims priority to Chinese Patent Application No. 202111529029.5, titled “SEMICONDUCTOR DEVICE AND METHOD FOR MANUFACTURING THE SAME”, filed on Dec. 14, 2021 with the China National Intellectual Property Administration, which is incorporated herein by reference in its entirety.

### FIELD

The present disclosure relates to the field of semiconductor manufacturing, and in particular to a semiconductor device and a method for manufacturing the semiconductor device.

### BACKGROUND

A vertical transistor refers to a transistor in which a source, a channel, and a drain are vertically stacked. Such transistor has good device characteristics, for example, good electrostatic properties, good control on the short channel effect, and small subthreshold leakage, which reduce power consumption, and is capable to further expand devices and increase an integration density in integrated circuits. Conventional manufacturing process results in low reliability in the vertical transistors.

### SUMMARY

In view of the above, embodiments of the present disclosure is to provide a semiconductor device and a method for manufacturing the semiconductor device, in order to realize self-alignment between a gate contact and a gate and improve reliability of the device.

A method for manufacturing a semiconductor device is provided according to an embodiment of the present disclosure, including: providing a substrate, where a first source-drain layer, a channel layer, and a second source-drain layer are stacked on the substrate in the above-listed sequence, both a gate dielectric layer and a gate structure surround the channel layer laterally, the gate structure includes a first portion extending laterally and a second portion extending upward from a periphery of the first portion, and the second portion is located at a periphery of the second source-drain layer: forming a spacer layer at an outer sidewall of the gate structure: etching the gate structure to reduce a vertical dimension of the gate structure: forming a sacrificial structure covering the gate structure, and forming a capping layer covering the second source-drain layer, the sacrificial structure, and the spacer layer: etching the capping layer to obtain a first contact hole reaching the sacrificial structure: removing the sacrificial structure at a bottom of the first contact hole to form a gap under the first contact hole: and forming a first contact structure in the first contact hole and the gap.

In an embodiment, a first dielectric layer surrounding the first source-drain layer is formed at a sidewall of the first source-drain layer, and a second dielectric layer surrounding the second source-drain layer is formed at a sidewall of the second source-drain layer. A first recess is formed by a sidewall of the channel layer with respect to the first dielectric layer and the second dielectric layer, and the gate dielectric layer and the gate structure are formed in the first recess. The second portion extending reaches a sidewall of the second dielectric layer before forming the spacer layer at the outer sidewall of the gate structure.

In an embodiment, the gate structure further includes a third portion extending downward and reaching the sidewall of the first dielectric layer.

In an embodiment, after the first source-drain layer, the channel layer, and the second source-drain layer, which are sequentially stacked, are patterned through etching, the first dielectric layer and the second dielectric layer are formed by: etching the channel layer from the sidewall of the channel layer to obtain a third recess, where the third recess is formed by a sidewall of the etched channel layer with respect to the first source-drain layer and the second source-drain layer: forming a dummy gate structure in the third recess: etching the first source-drain layer from the sidewall of the first source-drain layer to obtain a fourth recess, where the fourth recess is formed by a sidewall of the etched first source-drain layer with respect to the dummy gate structure: etching the second source-drain layer from the sidewall of the second source-drain layer to obtain a fifth recess, where the fifth recess is formed by a sidewall of the etched second source-drain layer with respect to the dummy gate structure: forming the first dielectric layer in the fourth recess: and forming the second dielectric layer in the fifth recess.

In an embodiment, a second recess is formed by a sidewall of the channel layer with respect to the first source-drain layer and the second source-drain layer, and the gate dielectric layer and the gate structure are formed in the second recess. The gate structure extends to the sidewall of the second source-drain layer before the spacer layer is formed at the outer sidewall of the gate structure. A lower surface of the gate structure is higher than an upper surface of the first source-drain layer. Before forming the sacrificial structure covering the gate structure, the method further includes forming an isolation layer on the sidewall of the second source-drain layer.

In an embodiment, the method further includes: etching the capping layer to obtain a second contact hole reaching the second source-drain layer: and forming a second contact structure in the second contact hole.

In an embodiment, the sacrificial structure is removed through wet etching.

A semiconductor device is provided according to an embodiment of the present disclosure. The semiconductor device includes: a first source-drain layer, a channel layer, a second source-drain layer, a gate dielectric layer, which are stacked on a substrate in the above-listed sequence: a gate dielectric layer and a gate structure, both of which surround the channel layer laterally, where the gate structure extends laterally: a first contact structure contacting the gate structure, where the first contact structure includes a fourth portion and a fifth portion which are vertically aligned, the fourth portion contacts the gate structure and the fifth portion contacts the fourth portion, and a lateral dimension of the first contact structure is different from a lateral dimension of the fifth portion: and a spacer layer, located at an outer sidewall of the gate structure and an outer sidewall of the fourth portion.

In an embodiment, a first dielectric layer surrounding the first source-drain layer is located at a sidewall of the first source-drain layer, and a second dielectric layer surrounding the second source-drain layer is located at a sidewall of the second source-drain layer. A first recess is formed by a sidewall of the channel layer with respect to the first dielectric layer and the second dielectric layer. The gate dielectric layer and the gate structure are located in the first recess, and the fourth portion is located at a sidewall of the second dielectric layer.

In an embodiment, a second recess is formed by a sidewall of the channel layer with respect to the first source-drain layer and the second source-drain layer. The gate dielectric layer and the gate structure are located in the second recess. The fourth portion is located on a sidewall of the second dielectric layer. A lower surface of the gate structure is higher than an upper surface of the first source-drain layer. An isolation layer is formed between the second source-drain layer and the fourth portion.

The semiconductor device and the method for manufacturing the semiconductor device are provided according to embodiments of the present disclosure. The substrate is provided. The first source-drain layer, the channel layer, and the second source-drain layer are sequentially stacked on the substrate. Both the gate dielectric layer and the gate structure surround the channel layer laterally. The gate structure includes the first portion extending laterally and the second portion extending upward from the periphery of the first portion. The second portion is located at the periphery of the second source-drain layer. The spacer layer is formed at the outer sidewall of the gate structure. The gate structure is etched to reduce a thickness of the gate structure. The sacrificial structure covering the gate structure is formed, and the capping layer covering the second source-drain layer, the sacrificial structure, and the spacer layer is formed. In one embodiment, the sacrificial structure is located at the periphery of the second source-drain layer and enclosed by the spacer layer. The capping layer is etched to obtain the first contact hole reaching the sacrificial structure.

The sacrificial structure at the bottom of the first contact hole is removed to form the gap under the first contact hole. The first contact structure is formed in the first contact hole and the gap. When forming the first contact structure, the spacer layer can limit a position of the first contact structure, achieving self-alignment between a bottom of the first contact structure and the gate structure. Hence, contact between the first contact structure and the gate structure has higher quality, the device has higher reliability, and a requirement on manufacture precision is reduced.

### BRIEF DESCRIPTION OF THE DRAWINGS

For clearer illustration of the embodiments of the present disclosure or conventional techniques, hereinafter briefly described are the drawings to be applied in embodiments of the present disclosure or conventional techniques. Apparently, the drawings in the following descriptions are only some embodiments of the present disclosure.

FIG. 1 is a flowchart of a method for manufacturing a semiconductor device according to an embodiment of the present disclosure.

FIG. 2A to FIG. 33 are schematic structural diagrams of a semiconductor device when manufactured through a method according to an embodiment of the present disclosure.

### DETAILED DESCRIPTION

In order to facilitate understanding of the embodiments of the present disclosure, hereinafter some embodiments of the present disclosure are described in detail in conjunction with the drawings.

Various some details are set forth in following description to facilitate a full understanding of the present disclosure. The present disclosure may be implemented in a manner different from those described herein. Therefore, the present disclosure is not limited by the some embodiments disclosed hereinafter.

In addition, the present disclosure is described in detail in conjunction with schematic diagrams. In order to facilitate explanation, when describing embodiments of the present disclosure in detail, a cross-sectional view of a device structure may not show parts that are enlarged to scale. The schematic diagrams are only exemplary, and shall not limit the protection scope of the present disclosure. In addition, three-dimensional spatial dimensions, including a length, a width, and a depth should be considered in actual manufacturing.

A vertical transistor refers to a transistor in which a source, a channel, and a drain are vertically stacked. Such transistor has good device characteristics, for example, good electrostatic properties, good control on the short channel effect, and small subthreshold leakage, which reduce power consumption, and is capable to further expand devices and increase an integration density in integrated circuits. Conventional manufacturing process results in low reliability in the vertical transistors. In practice, a gate contact and a gate structure are subject to poor alignment in conventional technology. One issue in this field is how to achieve self-alignment between the gate contact and the gate structure, and reduce costs while ensuring reliability of a transistor.

In view of the above, a semiconductor device and a method for manufacturing the semiconductor device are provided according to embodiments of the present disclosure. A substrate is provided. A first source-drain layer, a channel layer, and a second source-drain layer are sequentially stacked on the substrate. Both a gate dielectric layer and a gate structure surround the channel layer laterally. The gate structure includes a first portion extending laterally and a second portion extending upward from a periphery of the first portion. A second portion is located at a periphery of the second source-drain layer. A spacer layer is formed at an outer sidewall of the gate structure. The gate structure is etched to reduce a thickness of the gate structure. A sacrificial structure covering the gate structure is formed, and a capping layer covering the second source-drain layer, the sacrificial structure, and the spacer layer is formed. In one embodiment, the sacrificial structure is located at the periphery of the second source-drain layer and enclosed by the spacer layer. The capping layer is etched to obtain a first contact hole reaching the sacrificial structure. The sacrificial structure at the bottom of the first contact hole is removed to form a gap under the first contact hole. A first contact structure is formed in the first contact hole and the gap. When forming the first contact structure, the spacer layer can limit a position of the first contact structure, achieving self-alignment between a bottom of the first contact structure and the gate structure. Hence, contact between the first contact structure and the gate structure has higher quality, the device has higher reliability, and a requirement on manufacture precision is reduced.

For better understanding the embodiments of the present disclosure, hereinafter some embodiments are described in detail in conjunction with the drawings.

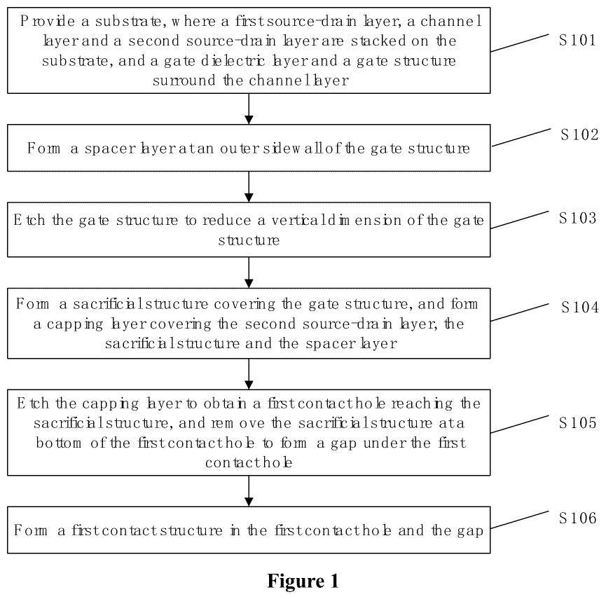

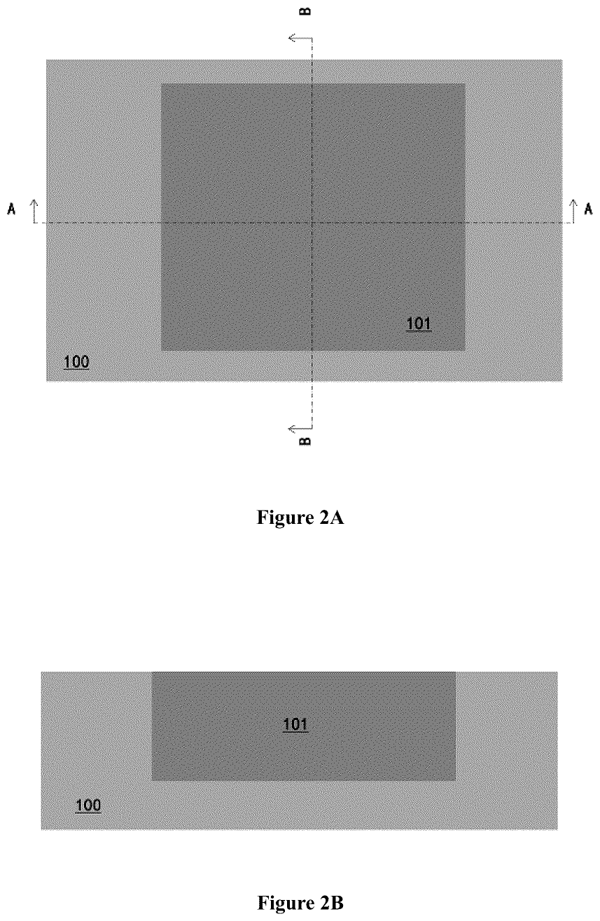

Reference is made to FIG. 1, which is a flowchart of a method for manufacturing a semiconductor device according to an embodiment of the present disclosure, and FIGS. 2A to 33, which are schematic structural diagrams of a semiconductor device manufactured through the method. The method includes steps S101 to S106.

In step S101, a substrate 100 is provided. Reference is made to FIGS. 2A to 12B and 21 to 24.

In an embodiment, the substrate 100 is a semiconductor substrate, such as a Si substrate, a Ge substrate, a SiGe substrate, an SOI (silicon-on-insulator) substrate, or a GOI (germanium-on-insulator) substrate. In another embodiment, the semiconductor substrate may be a substrate including another elemental semiconductor or a compound semiconductor, such as GaAs, InP or SiC, or may be a stacked structure, such as Si/SiGe. The semiconductor substrate may be another epitaxial structure, such as an SGOI (silicon-germanium-on-insulator). In this embodiment, the substrate 100 is a silicon substrate for supporting device structures thereon.

Reference is made to FIGS. 2A and 2B. FIG. 2A is a top view of a semiconductor device, and FIG. 2B is a cross-sectional view of the semiconductor device along line AA. There may be a well region 101 in the substrate 100, which is obtained by doping the substrate 100. In an n-type field-effect transistor (FET), the well region 101 may be p-type doped, for example, with B or In, and a concentration of dopants may range from 1e17cm⁻³ to 2e19cm⁻³. In a p-type FET, the well region 101 may be n-type doped, for example, with As or P, and a concentration of dopants may range from 1e17cm⁻³ to 2e19cm⁻³. The well region 101 may be shaped on requirement through ion implantation and thermal annealing. The well region 101 is capable to isolate the substrate 100 from the semiconductor device located thereon, hence preventing a current leakage from the semiconductor device into the substrate 100.

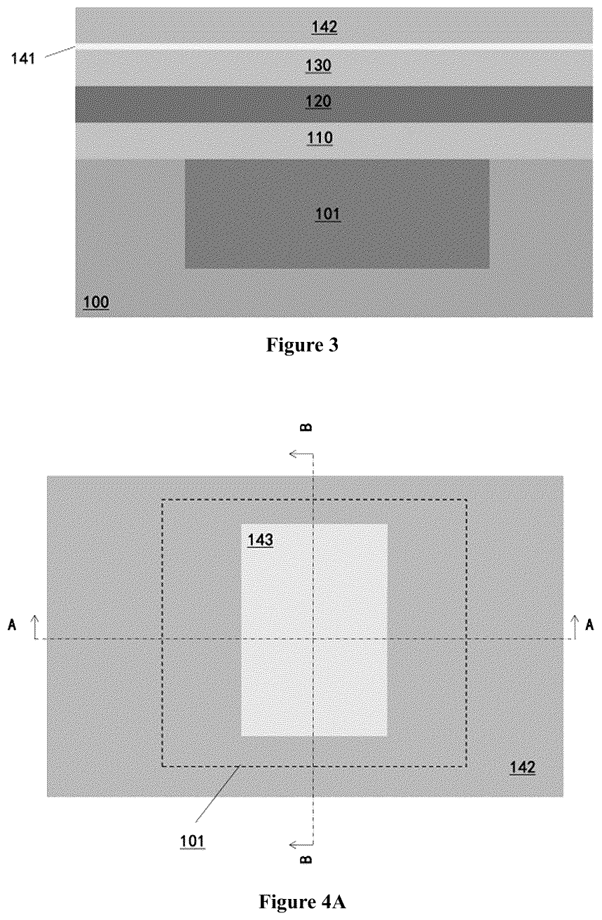

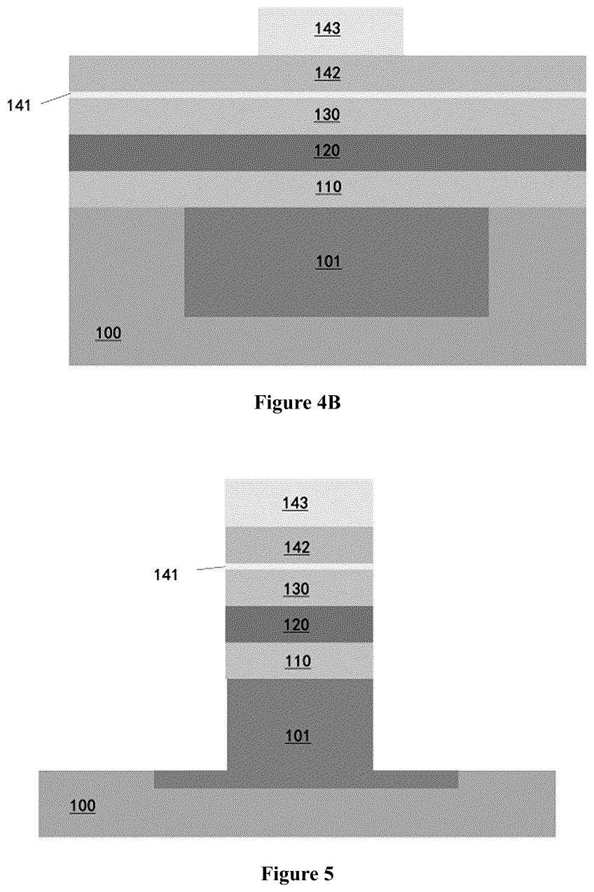

A first source-drain layer 110, a channel layer 120, and a second source-drain layer 130 are stacked on the substrate 100 in the above-listed sequence. One of the first source-drain layer 110 and the second source-drain layer 130 serves as a source, and the other serves as a drain. In an embodiment, the first source-drain layer 110 covering the substrate 100, the channel layer 120 covering the first source-drain layer 110, and the second source-drain layer 130 covering the channel layer 120 may be formed on the substrate. Reference is made to FIG. 3, which is a cross-sectional view of the semiconductor structure along the line AA. Then, the second source-drain layer 130, the channel layer 120, and the first source-drain layer 110 are etched into a desired shape, that is, the first source-drain layer 110, the channel layer 120, and the second source-drain layer 130 are patterned. Reference is made to FIGS. 4A, 4B, and 5. FIG. 4A is a top view of a semiconductor device according to another embodiment of the present disclosure, and FIG. 4B is a cross-sectional view of the semiconductor device as shown in FIG. 4A along the line AA.

In an embodiment, a first semiconductor layer covering the substrate 100 may be formed on the substrate 100 through epitaxy (EPI), and the first semiconductor is doped to obtain the first source-drain layer 110. The first semiconductor layer may be made of silicon, and may be in-situ doped. In a p-type FET, the dopant may be a p-type dopant such as B or In, and have a concentration ranging from 1e18cm⁻³ to 2e20cm⁻³. In an n-type FET, the dopant may be an n-type dopant such as As or P, and have a concentration ranging from 1e18 cm⁻³ to 1e21 cm⁻³. A thickness of the first source-drain layer 110 may range from 10 nm to 50 nm.

In an embodiment, the channel layer 120 covering the first source-drain layer 110 may be formed through EPI, and the channel layer 120 may or may not be doped. The channel layer 120 may be made of silicon germanium, where a quantity ratio of germanium molecules to total molecules ranges from 10% to 40%. A thickness of the channel layer 120 defines a vertical length of a channel, and also defines a gate length to some extent. Such thickness is for control on electrical characteristics of the device, for example, on the short channel effect. The thickness of the channel layer 120 may range from 10 nm to 100 nm.

In an embodiment, a second semiconductor layer covering the channel layer 120 may be formed through epitaxy. The second semiconductor layer may be doped to obtain the second source-drain layer 130. The second semiconductor layer may be made of silicon, and may be in-situ doped. In a p-type FET, the dopant may be a p-type dopant such as B or In, and have a concentration ranging from 1e18cm-3 to 2e20cm3. In an n-type FET, the dopant may be an n-type dopant such as As or P, and have a concentration ranging from 1e18 cm⁻³ to 1e21 cm⁻³. A thickness of the second source-drain layer 130 may range from 10 nm to 50 nm.

In a MOS device, the first source-drain layer 110 and the second source-drain layer 130 may be both p-type doped or both n-type doped. In a tunnel FET (TFET), the first source-drain layer 110 and the second source-drain layer 130 may be oppositely doped.

In an embodiment, a dielectric layer may be formed on the second source-drain layer 130. The dielectric layer may protect the second source-drain layer 130, and may serve as a hard mask for subsequent etching on the second source-drain layer 130, the channel layer 120, and the first source-drain layer 110. In an embodiment, the dielectric layer may include a protective layer 141 and a hard mask layer 142 on the protective layer 141. The protective layer 141 is configured to protect the second source-drain layer 130, and serves as an etch stop layer for the hard mask layer 142. The protective layer 141 may be made of oxide, such as thermal oxide. The protective layer 141 may have a thickness ranging from 2 nm to 5 nm, and is obtained by thermally oxidizing a surface of the second source-drain layer 130. The hard mask layer 142 may be made of nitride or a low dielectric constant (low-K) material, such as a silicon-carbide-based material. The hard mask layer 142 may have a thickness ranging from 10 nm to 100 nm.

Reference is made to FIGS. 4A and 4B. A patterned photoresist layer 143 may be formed on the dielectric layer. A lateral dimension of the photoresist layer 143 may be less than a lateral dimension of the well region 101, and functional film layers that are formed are limited within the well region 101, ensuring reliability of the device. On a basis of FIG. 4B, a pattern of the photoresist layer 143 is transferred to the dielectric layer. The second source-drain layer 130, the channel layer 120, and the first source-drain layer 110 are etched by using the patterned dielectric layer as a mask. In one embodiment, the second source-drain layer 130, the channel layer 120, and the first source-drain layer 110 are shaped on requirement, as shown in FIG. 5. The substrate 100 within the well region 101 may also be etched to further improve reliability of the device.

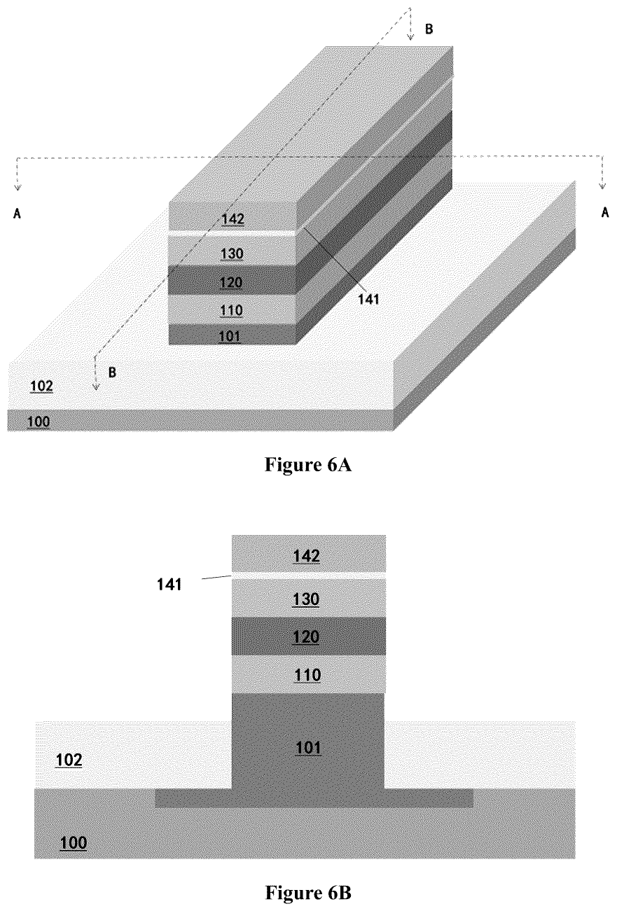

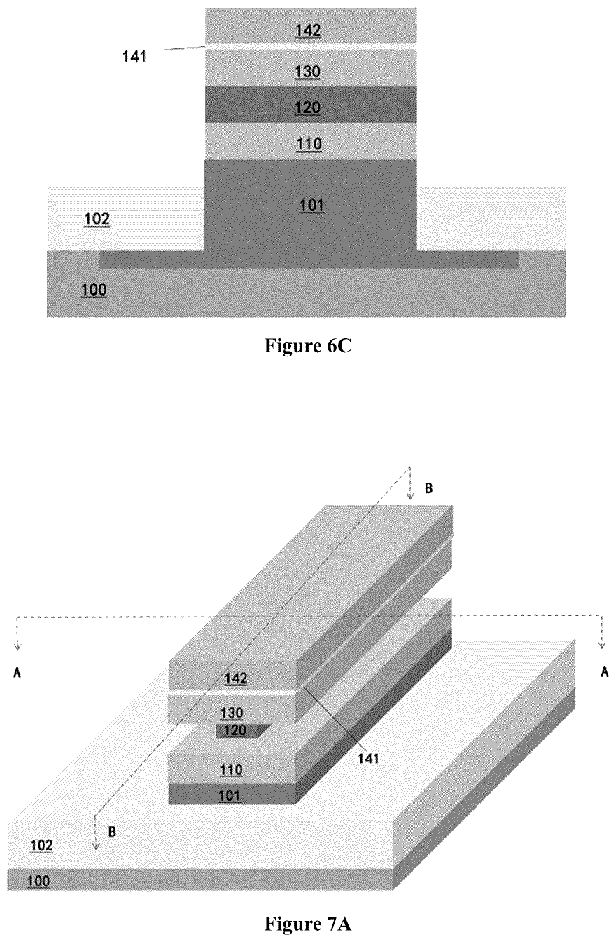

After the second source-drain layer 130, the channel layer 120, and the first source-drain layer 110 are etched, the photoresist layer 143 may be removed and a shallow trench isolation (STI) 102 may be formed on the substrate 100. The STI 102 is configured to isolate different devices from each other. In a case that the substrate 100 within the well region 101 is etched, the shallow trench isolation 102 may surround a sidewall of the well region 101 that is located under the first source-drain layer 110, and to isolate different well regions 101 from each other. The shallow trench isolation 102 may cover the entire sidewall of the well region 101, or may only cover a lower portion of the sidewall of the well region 101. Reference is made to FIGS. 6A to 6C. FIG. 6A is a three-dimensional structural diagram of a semiconductor device. FIG. 6B is a cross-sectional view of the semiconductor device as shown in FIG. 6A along the line AA. FIG. 6C is a cross-sectional view of the semiconductor device as shown in FIG. 6A along line BB.

In some scenarios, the shallow trench isolation 102 may cover a sidewall of the first source-drain layer 110, to protect the first source-drain layer 110 and isolate the first source-drain layer 110 from other film layers, for example, a semiconductor layer or a conductor layer.

The shallow trench isolation 102 may be obtained through deposition and etching. In an embodiment, an isolation material may be deposited. Then, the isolation material above the surface of the dielectric layer may be removed through etching, and the isolation material at the sidewall of the second source-drain layer 130, the sidewall of the channel layer 120, and the sidewall of the first source-drain layer 110 may be removed through etching. The remained isolation material on the substrate 100 is planarized. In one embodiment, the isolation material at the sidewall of the first source-drain layer 110 may not be etched when necessary: The isolation material may be etched or removed through, for example, wet etching, vapor etching, or vapor HF.

After the shallow trench isolation 102 is formed, a gate dielectric layer 151 and a gate structure 150 around the channel layer 120 may be formed. The gate dielectric layer 151 and the gate structure 150, after being formed, surround the channel layer 120 in a lateral plane. The gate structure 150 may have a first portion extending laterally and a second portion extending upward from a periphery of the first portion. The second portion may be located at a periphery of the second source-drain layer 130.

Two types of structures are provided according to embodiments of the present disclosure. In a first structure, a first dielectric layer 111 surrounding the first source-drain layer 110 is formed at the sidewall of the first source-drain layer 110, and a second dielectric layer 131 surrounding the second source-drain layer 130 is formed at the sidewall of the second source-drain layer 130. A first recess is formed by the sidewall of the channel layer 120 with respect to the first dielectric layer 111 and the second dielectric layer 131, and the gate dielectric layer 151 and the gate structure 150 are formed in the first recess. In a second structure, a second recess is formed by the sidewall of the channel layer 120 with respect to the first source-drain layer 110 and the second source-drain layer 130, and the gate dielectric layer 151 and the gate structure 150 are formed in the second recess. Hereinafter the two types of structures are described in detail.

In the first structure, the second dielectric layer 131 is formed at the periphery of the second source-drain layer 130. In such case, the second portion of the gate structure 150 may extend and reach the sidewall of the second dielectric layer 131, and the second dielectric layer 131 isolates the second source-drain layer 130 from the second portion. The shallow trench isolation 102 may not cover the sidewall of the first source-drain layer 110, since the first dielectric layer 111 surrounding the first source-drain layer 110 would be formed. In one embodiment, the first dielectric layer 111 covers the first source-drain layer 110, and hence the gate structure 150 may further have a third portion extending downward, which reaches the sidewall of the first dielectric layer 111. The first dielectric layer 111 isolates the third portion from the first source-drain layer 110.

When manufacturing the first structure, the first dielectric layer 111 surrounding the first source-drain layer 110 and the second dielectric layer 131 surrounding the second source-drain layer 130 may be first formed, and then the gate dielectric layer 151 and the gate structure 150 are formed in the first recess formed by the channel layer 120 with respect to the first dielectric layer 111 and the second dielectric layer 131.

The first dielectric layer 111 and the second dielectric layer 131 may be formed through following steps.

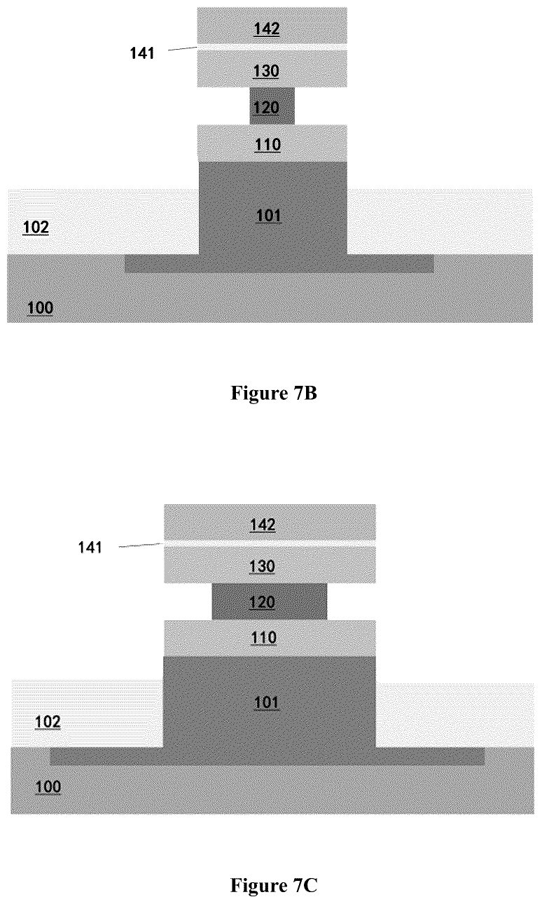

After the first source-drain layer 110, the channel layer 120, and the second source-drain layer 130 that are sequentially stacked are patterned through etching, the channel layer 120 is etched from the sidewall of the channel layer 120 to obtain a third recess. The third recess is formed by a sidewall of the etched channel layer 120 with respect to the first source-drain layer 110 and the second source-drain layer 130. Reference is made to FIGS. 7A to 7C. FIG. 7A is a three-dimensional schematic structural diagram of a semiconductor device according to an embodiment of the present disclosure. FIG. 7B is a cross-sectional view of the semiconductor structure as shown in FIG. 7A along the line AA. FIG. 7C is a cross-sectional view of the semiconductor structure as shown in FIG. 7A along the line BB.

In an embodiment, after the first source-drain layer 110, the channel layer 120, and the second source-drain layer 130 are patterned through etching, the etched first source-drain layer 110, the etched second source-drain layer 130, and the etched channel layer 120 have sidewalls that are substantially flush, because they are etched under the same hard mask layer 142. Then, the channel layer 120 is further etched from a current sidewall of the channel layer 200 to reduce a lateral dimension thereof. A depth of etching on the channel layer 120 is mainly configure to define a current flow and a lateral size of the device. The larger the lateral size of the remained channel layer 120 is, the larger a current is permitted in a vertical channel formed by the channel layer 120, and the larger a lateral size of the corresponding device is. The channel layer 120 may be etched through atomic-layer etching, to achieve a good control on a shape of the channel.

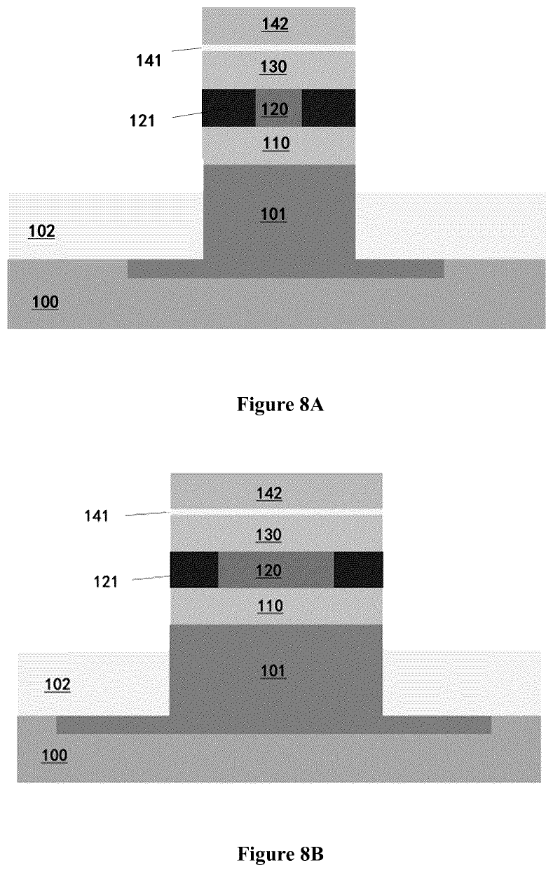

Afterwards, a dummy gate structure 121 is formed in the third recess. Reference is made to FIGS. 8A and 8B. FIG. 8A is a cross-sectional view of a semiconductor structure along the line AA, and FIG. 8B is a cross-sectional view of the semiconductor structure along the line BB. The third recess is filled with the dummy gate structure 121, and an outer sidewall of the dummy gate structure 121 may be flush with the sidewall of the first source-drain layer 110 and the sidewall of the second source-drain layer 130. In one embodiment, the channel layer 120 is surrounded and protected by the dummy gate structure 121. The dummy gate structure 121 may be made of oxynitride, silicon carbide, or the like. The dummy gate structure 121 and the hard mask layer 142 may be made of different materials, and hence may be removed separately.

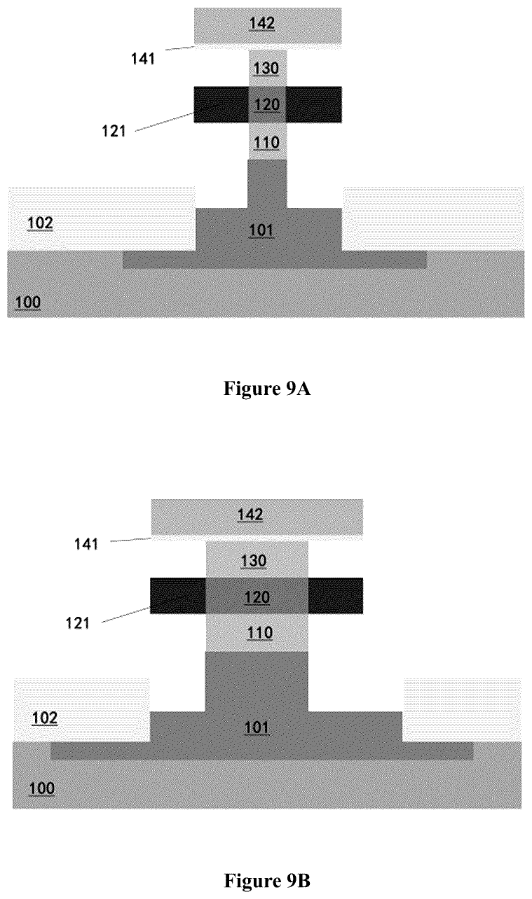

Afterwards, the first source-drain layer 110 is etched from the sidewall of the first source-drain layer 110 to obtain a fourth recess, and the second source-drain layer 130 is etched from the sidewall of the second source-drain layer 130 to obtain a fifth recess. The fourth recess is formed by a sidewall of the etched first source-drain layer 110 with respect to the dummy gate structure 121, and the fifth recess is formed by a sidewall of the etched second source-drain layer 130 with respect the dummy gate structure 121. Reference is made to FIGS. 9A and 9B. FIG. 9A is a cross-sectional view of a semiconductor structure along the line AA, and FIG. 9B is a cross-sectional view of the semiconductor structure along the line BB. When etching the first source-drain layer 110 and the second source-drain layer 130, the channel layer 120 is not damaged as long as it is not exposed. After the first source-drain layer 110 and the second source-drain layer 130 have been laterally etched, the sidewall of the first source-drain layer 110 may be flush with the sidewall of the channel layer 120, and the sidewall of the second source-drain layer 130 may be flush with the channel layer 120. The sidewall of the channel layer 120 may still be recessed with respect to the first source-drain layer 110, or may still be recessed with respect to the second source-drain layer 130. The lateral etching on the first source-drain layer 110 and the second source-drain layer 130 is capable to reduce an overcapacitance between the source (or the drain) and the gate. Lateral dimensions of the first source-drain layer 110 and the second source-drain layer 130 are reduced after the etching. The well region 101 under the first source-drain layer 110 may also be etched when etching the first source-drain layer 110, and hence a lateral dimension at a top of the well region 101 is reduced.

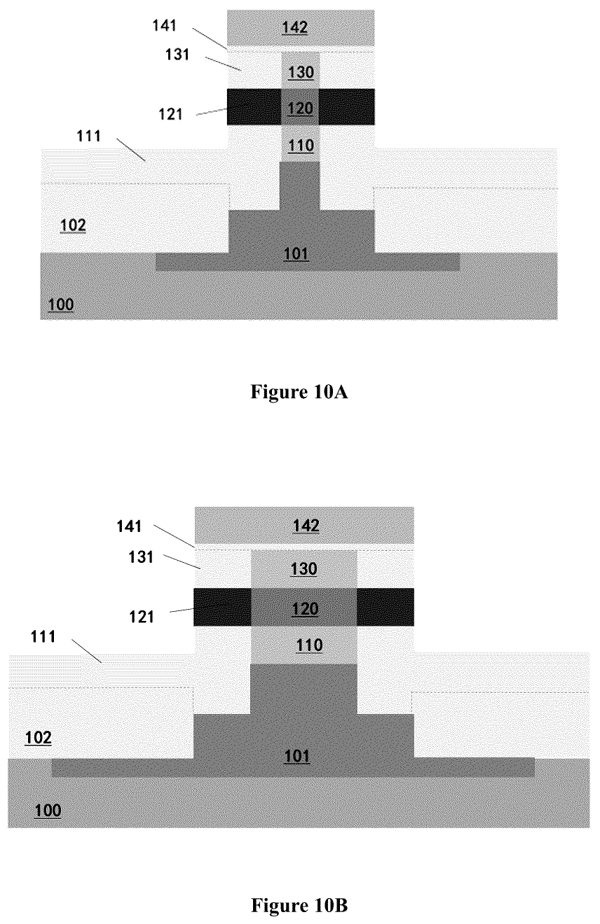

Afterwards, the first dielectric layer 111 is formed in the fourth recess, and the second dielectric layer 131 is formed in the fifth recess. Reference is made to FIGS. 10A and 10B. FIG. 10A is a cross-sectional view of a semiconductor structure along the line AA, and FIG. 10B is a cross-sectional view of the semiconductor structure along the line BB. The first dielectric layer 111 and the second dielectric layer 131 may both be oxide layers, may be formed through a same process, and are differently named due to their different positions. In an embodiment, oxide may be deposited and then etched back to expose the dummy gate structure 121, to obtain the first dielectric layer 111 and the second dielectric layer 131. The first dielectric layer 111 may extend laterally and reaches the shallow trench isolation 102, and an upper surface of the first dielectric layer 111 is lower than a lower surface of the dummy gate structure 121. The upper surface of the first dielectric layer 111 outside the fourth recess may be lower than the upper surface of the first dielectric layer 111 within the fourth recess. The second dielectric layer 131 is formed in the fifth recess. The first dielectric layer 111 and the shallow trench isolation 102 may be made of a same material and formed in different processes, and therefore they are separated by dotted lines when shown in the drawings to facilitate distinguishing one from another. The second dielectric layer 131 and the protective layer 141 may be made of a same material and formed in different processes, and therefore they are separated by dotted lines when shown in the drawings to facilitate distinguishing one from another.

After the first dielectric layer 111 and the second dielectric layer 131 are formed, the gate dielectric layer 151 and the gate structure 150 may be formed in the first recess through the following steps.

The dummy gate structure 121 in the first recess is removed. The hard mask layer 142 may not be etched when removing the dummy gate structure 121. Then, the gate dielectric layer 151 covering a surface of the first recess is formed in the first recess. That is, the gate dielectric layer 151 covers an upper surface of the first source-drain layer 110, a sidewall of the channel layer 120, and a lower surface of the second source-drain layer 130. In an embodiment, a gate dielectric material layer may be deposited, and then the gate dielectric material layer may be etched to retain only a part within the first recess as the gate dielectric layer 151. The gate dielectric layer 151 is made of a high-K dielectric layer.

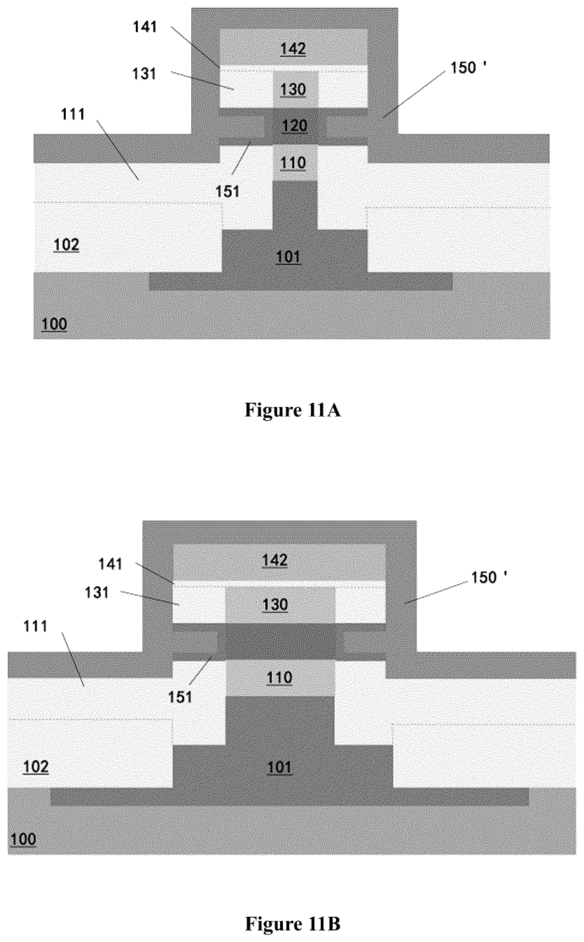

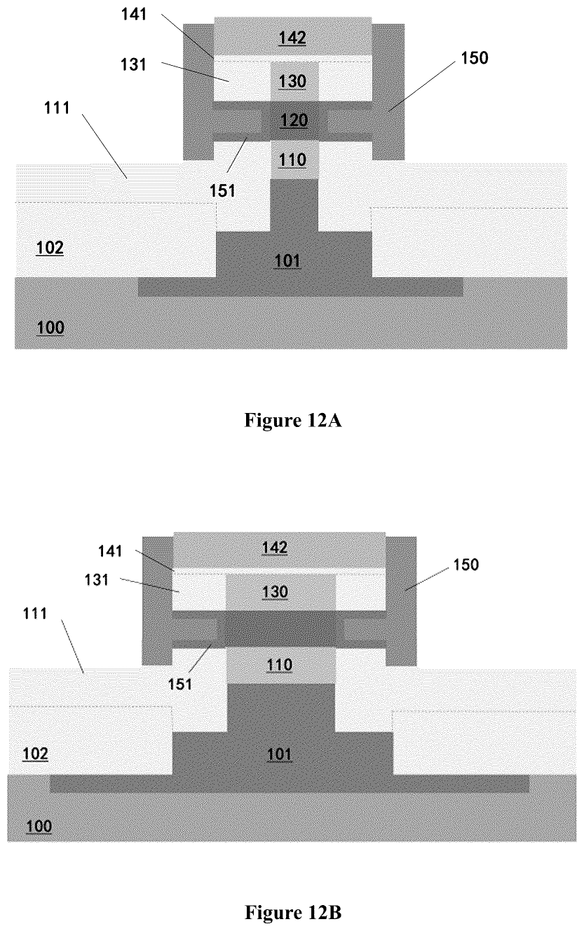

Afterwards, the gate structure 150 is formed. In an embodiment, a gate material 150′ may be deposited, and the deposited gate material 150′ is located both inside and outside the first recess. Reference is made to FIGS. 11A and 11B. FIG. 11A is a cross-sectional view of a semiconductor structure along the line AA, and FIG. 11B is a cross-sectional view of the semiconductor structure along the line BB. The gate material 150′ is etched to obtain the gate structure 150. The gate dielectric layer 151 is disposed between the channel layer 120 and the gate structure 150, and the obtained gate structure 150 surrounds the channel layer 120 in the lateral plane. The gate structure 150 may have a first portion extending laterally and a second portion extending upward from a periphery of the first portion. The second portion may be located at the periphery of the second source-drain layer 130. Reference is made to FIGS. 12A and 12B. FIG. 12A is a cross-sectional view of a semiconductor structure along the line AA, and FIG. 12B is a cross-sectional view of the semiconductor structure along the line BB. The gate structure 150 may further have a third portion extending downward to the sidewall of the first dielectric layer 111, and the first dielectric layer 111 isolates the third portion from the first source-drain layer 110. In addition, the second portion of the gate structure 150 may extend to the sidewall of the hard mask layer 142, that is, an upper surface of the second portion may be higher than an upper surface of the second source-drain layer 130.

In the second structure, the second recess is formed by the sidewall of the channel layer 120 with respect to the first source-drain layer 110 and the second source-drain layer 130. In a case that the sidewall of the first source-drain layer 110 is not provided with a dielectric layer, the gate structure 150) does not extend to the sidewall of the first source-drain layer 110, and a lower surface of the gate structure 150 is higher than an upper surface of the first source-drain layer 110, and the gate structure 150 is isolated from the first source-drain layer 110. In an embodiment, after the first source-drain layer 110, channel layer 120, and second source-drain layer 130 are patterned through etching, the shallow trench isolation structure 102 covering the sidewall of the first source-drain layer 110 may be formed to prevent the gate structure 150 formed subsequently from contacting the sidewall of the first source-drain layer 110. Reference is made to FIG. 21, which is a cross-sectional view of a semiconductor structure along the line AA.

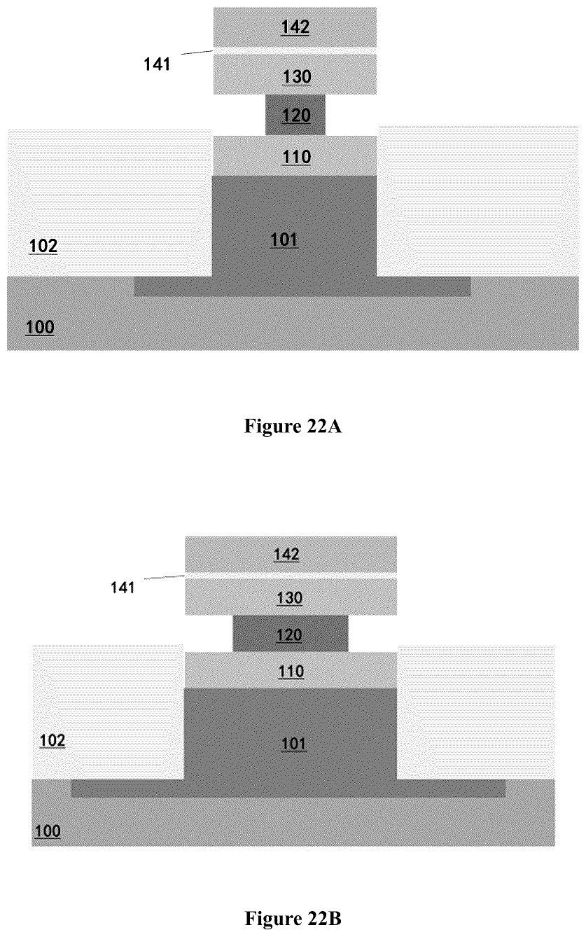

Afterwards, the channel layer 120 may be etched from a current sidewall of the channel layer 120 to obtain the second recess, which is formed by a sidewall of the etched channel layer 120 with respect to the first source-drain layer 110 and the second source-drain layer 130. Reference is made to FIGS. 22A and 22B. FIG. 22A is a cross-sectional view of a semiconductor structure along the line AA, and FIG. 22B is a cross-sectional view of the semiconductor structure along the line BB. Reference may be made to the foregoing description for etching the channel layer 120, which is not repeated herein. After the channel layer 120 is etched to obtain the second recess, the gate dielectric layer 151 may be formed in the second recess. Reference may be made to the foregoing description for forming the gate dielectric layer 151, which is not repeated herein.

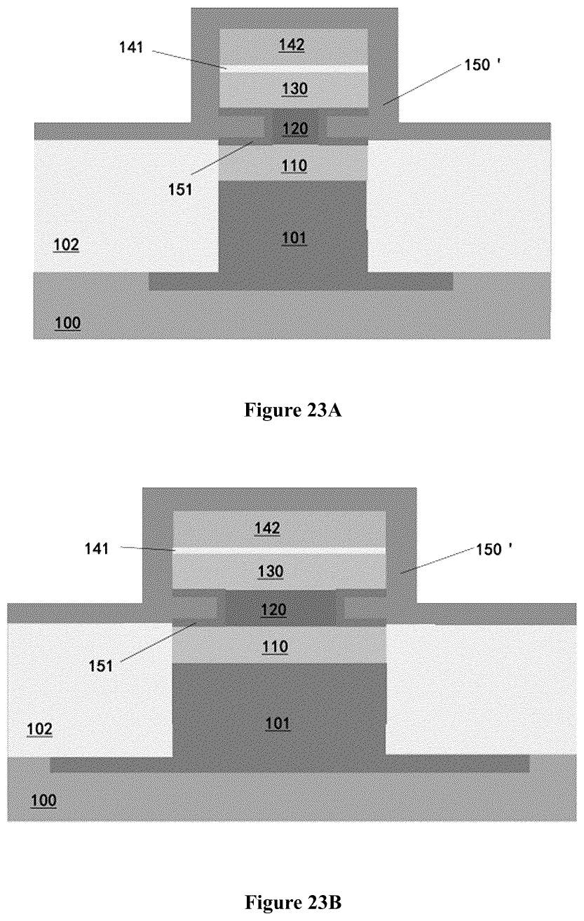

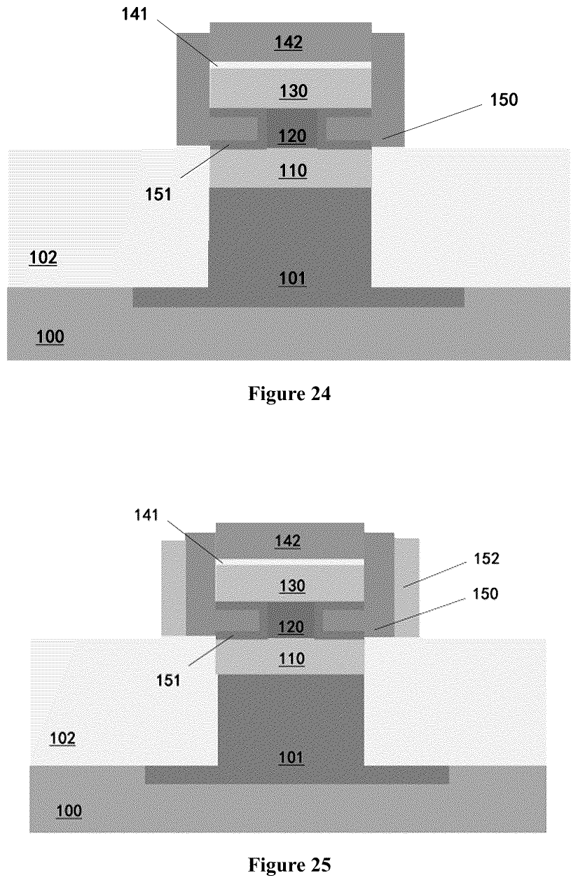

Afterwards, the gate structure 150 may be formed. In an example, a gate material 150′ may be deposited, and the formed gate material 150′ is located both inside and outside the first recess. Reference is made to FIGS. 23A and 23B. FIG. 23A is a cross-sectional view of a semiconductor structure along the line AA, and FIG. 23B is a cross-sectional view of the semiconductor structure along the line BB. The gate material 150′ may be not located at the sidewall of the first source-drain layer 110, since the shallow trench isolation 102 may cover the sidewall of the first source-drain layer 110. The gate material 150′ is etched to obtain the gate structure 150. The gate dielectric layer 151 is disposed between the channel layer 120 and the gate structure 150, and the obtained gate structure 150 surrounds the channel layer 120 in the lateral plane. The gate structure 150 may have a first portion extending laterally and a second portion extending upward from a periphery of the first portion. The second portion may be disposed at the periphery of the second source-drain layer 130. Reference is made to FIG. 24, which is a cross-sectional view of a semiconductor structure along the line AA. The gate structure 150 extends and reaches the sidewall of the second source-drain layer 130, and the lower surface of the gate structure 150 is higher than the upper surface of the first source-drain layer 110. In addition, the second portion of the gate structure 150 may extend and reach the sidewall of the hard mask layer 142. That is, an upper surface of the second portion may be higher than an upper surface of the second source-drain layer 130.

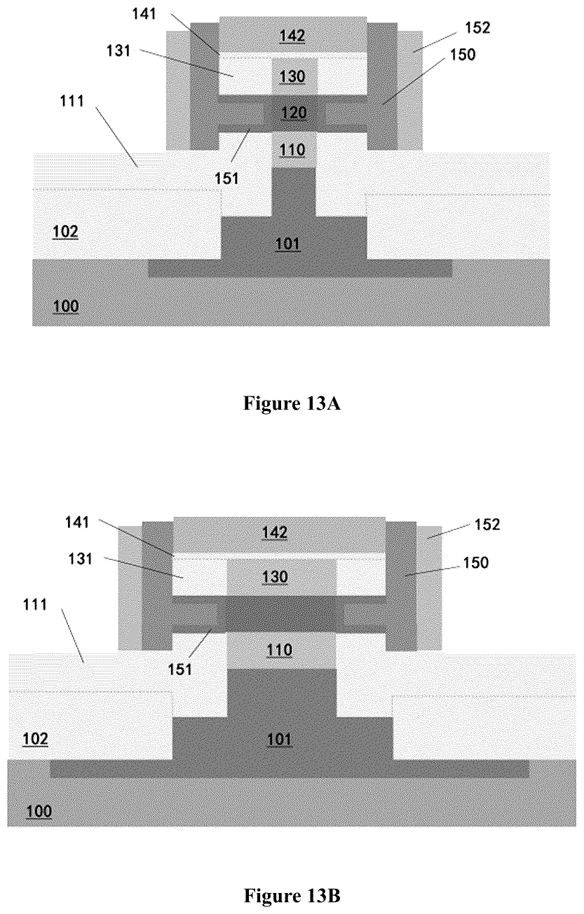

In step S102, a spacer layer 152 is formed at an outer sidewall of the gate structure 150. Reference is made to FIGS. 13A, 13B, and 25.

In an embodiment, after the gate structure 150 is formed, the spacer layer 152 may be formed at the outer sidewall of the gate structure 150 through deposition and etching.

When the gate structure 150 surrounds the channel layer 120, the spacer layer 152 may surround the gate structure 150 to form a closed shape in the lateral plane. The spacer layer 152 may be made of oxynitride, and a lateral dimension of the spacer layer 152 may range from 5 nm to 50 nm. The spacer layer 152 is formed along the outer sidewall of the gate structure 150. A position and an inner sidewall of the spacer layer 152 is determined by the gate structure 150. A vertical dimension of the spacer layer 152 may be same as or slightly less than a vertical dimension of the gate structure 150.

In the first structure, the semiconductor structure with the formed spacer layer 152 is as shown in FIGS. 13A and 13B. FIG. 13A is a cross-sectional view of a semiconductor structure along the line AA, and FIG. 13B is a cross-sectional view of the semiconductor structure along the line BB. In the second structure, the semiconductor structure with the formed spacer layer 152 is as shown in FIG. 25. FIG. 25 is a cross-sectional view of a semiconductor structure along the line AA.

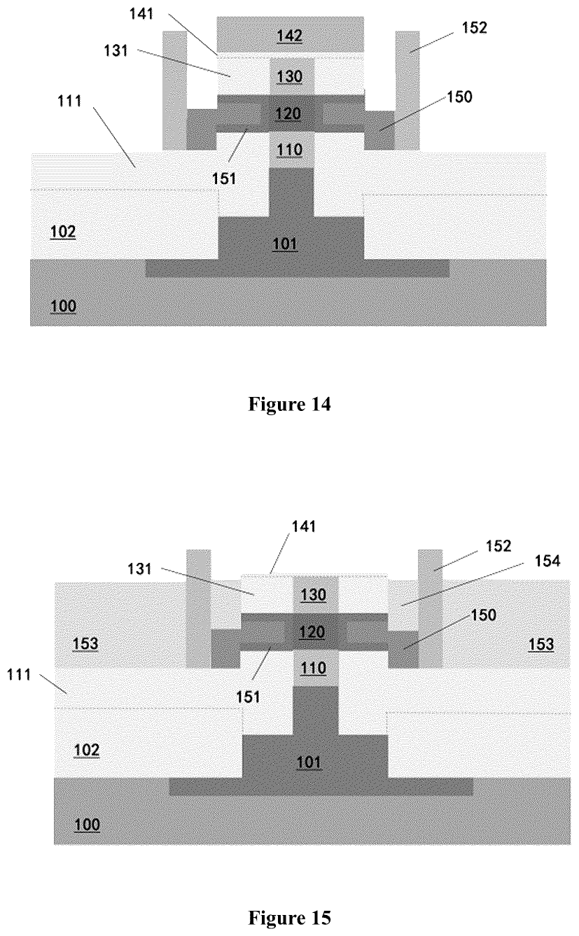

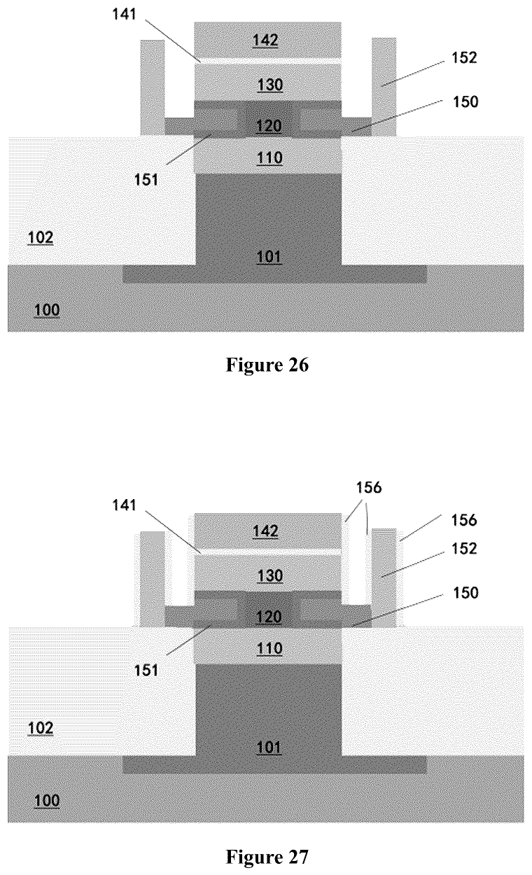

In step S103, the gate structure 150 is etched to reduce a vertical dimension of the gate structure 150. Reference is made to FIGS. 14 and 26.

After the spacer layer 152 is formed, the gate structure 150 may be etched to reduce the vertical dimension thereof. An upper surface of the etched gate structure 150 is higher than the upper surface of the gate dielectric layer 151 that is located on the first source-drain layer 110, and the remained gate structure 150 is an integrate structure.

In the first structure, the upper surface of the etched gate structure 150 may be lower than a lower surface of the gate dielectric layer 151 located at the lower surface of the second source-drain layer 130. The semiconductor structure after etching the gate structure 150 may be as shown in FIG. 14. FIG. 14 is a cross-sectional view of a semiconductor structure along the line AA. In one embodiment, the upper surface of the etched gate structure 150 may be higher than the lower surface of the second source-drain layer 130. Since the second dielectric layer 131 is formed at the sidewall of the second source-drain layer 130, a part of the gate structure 150, which is higher than the lower surface of the second source-drain layer 130, is isolated from the second source-drain layer 130 via the second dielectric layer 131.

In the second structure, the upper surface of the gate structure 150 is lower than a lower surface of the gate dielectric layer 151 located at the lower surface of the second source-drain layer 130. The semiconductor structure after etching the gate structure 150 may be as shown in FIG. 26. FIG. 26 is a cross-sectional view of a semiconductor structure along the line AA. The upper surface of the gate structure 150 may be higher than the lower surface of the gate dielectric layer 151 located at the lower surface of the second source-drain layer 130, and lower than the upper surface of the gate dielectric layer 151 located at the lower surface of the second source-drain layer 130. A reason lies in that no dielectric layer is provided at the sidewall of the second source-drain layer 130, and hence the gate structure 150 and the second source-drain layer 130 should not be in direct contact.

In step S104, a sacrificial structure 154 covering the gate structure 150 is formed, and a capping layer 160 covering the second source-drain layer 130, the sacrificial structure 154, and the spacer layer 152 is formed. Reference is made to FIGS. 15, 16, 27, 28, and 29.

In an embodiment, after the gate structure 150 is etched, a sacrificial structure 154 covering the gate structure 150 may be formed. The sacrificial structure 154 is located above the gate structure 150 and between the second source-drain layer 130 and the spacer layer 152. The sacrificial structure 154 may form a closed shape in the lateral plane. The sacrificial structure 154 may be made of nitride, and the sacrificial structure 154 may be formed through deposition and etching. When forming the sacrificial structure 154, a third dielectric layer 153 made of the same material as the sacrificial structure 154 may be simultaneously formed outside the spacer layer 152. In a case that the sacrificial structure 154 is made of the same material as the hard mask layer 142, the hard mask layer 142 may be removed in the above process of forming the sacrificial structure 154.

In the first structure, the semiconductor device after forming the sacrificial structure 154 may be as shown in FIG. 15. FIG. 15 is a cross-sectional view of a semiconductor structure along the line AA. The sacrificial structure 154 is formed above the gate structure 150, and is located between the second dielectric layer 131 and the spacer layer 152. The third dielectric layer 153 having the same material as the sacrificial structure 154 is located on the first dielectric layer 111.

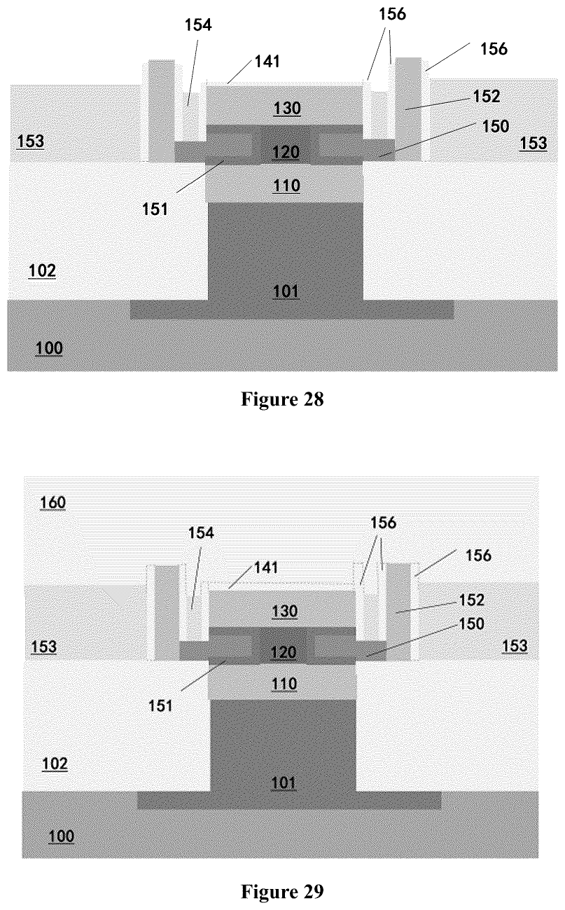

In the second structure, before forming the sacrificial layer, an isolation layer 156 may be formed at the sidewall of the second source-drain layer 130. The isolation layer 156 located at the sidewall of the second source-drain layer 130 is configured to isolate the second source-drain layer 130 from a first contact structure 163 which is formed in a subsequent step. The isolation layer 156 may be made of a high-K dielectric material, such as oxide. A lateral dimension of the isolation layer 156 ranges from 3 nm to 15 nm. The semiconductor device after forming the isolation layer 156 may be as shown in FIG. 27. FIG. 27 is a cross-sectional view of a semiconductor structure along the line AA. The isolation layer 156 may be located at the sidewall of the second source-drain layer 130, and at the sidewall of the hard mask layer 142. The isolation layer 156 when being formed may further be disposed at the sidewall of the spacer layer. After the isolation layer 156 is formed, the sacrificial structure 154 may be formed on the gate structure 150. The semiconductor device after forming the sacrificial structure 154 may be as shown in FIG. 28. FIG. 28 is a cross-sectional view of a semiconductor structure along the line AA. The sacrificial structure 154 is formed above the gate structure 150, and is located between two isolation layers 156.

In an embodiment, after the sacrificial structure 154 is formed, a capping layer 160 covering the second source-drain layer 130, the sacrificial structure 154, and the spacer layer 152 may be formed. The capping layer 160 may be made of oxide, such as silicon oxide. The capping layer 160 may be formed through deposition and etching. An upper surface of the capping layer 160 may be flat.

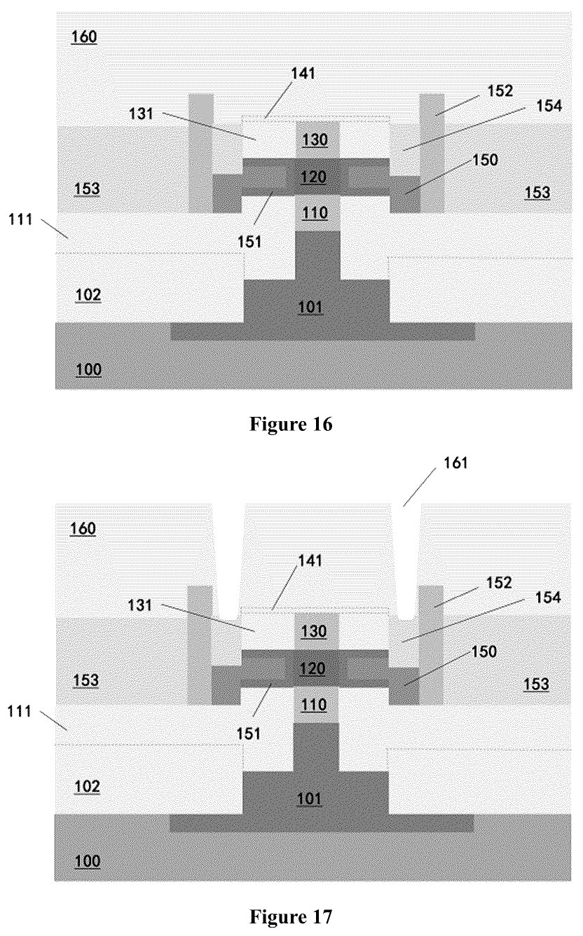

In the first structure, the semiconductor device after forming the capping layer 160 may be as shown in FIG. 16. FIG. 16 is a cross-sectional view of a semiconductor structure along the line AA. The capping layer 160 covers the protective layer 141, the sacrificial structure, the spacer layer 152, and the third dielectric layer 153.

In the second structure, the semiconductor device after forming the capping layer 160 may be as shown in FIG. 29. FIG. 29 is a cross-sectional view of a semiconductor structure along line AA. The capping layer 160 covers the protective layer 141, the sacrificial structure, the spacer layer 152, the isolation layer 156, and the third dielectric layer 153.

In step S105, the capping layer 160 is etched to obtain a first contact hole 161 reaching the sacrificial structure 154, the sacrificial structure 154 at a bottom of the first contact hole 161 is removed to form a gap 162 under the first contact hole 161. Reference is made to FIGS. 17, 18, 30, and 31.

In an embodiment, after the capping layer 160 is formed, the capping layer 160 may be etched to obtain the first contact hole 161 reaching the sacrificial structure 154, and a bottom of the first contact hole 161 contacts a top of the sacrificial structure 154. The sacrificial structure 154 serves as an etch stop layer for etching the first contact hole 161. In one embodiment, a part of the sacrificial structure 154 may be over-etched. The first contact hole 161 may be formed through anisotropic dry etching.

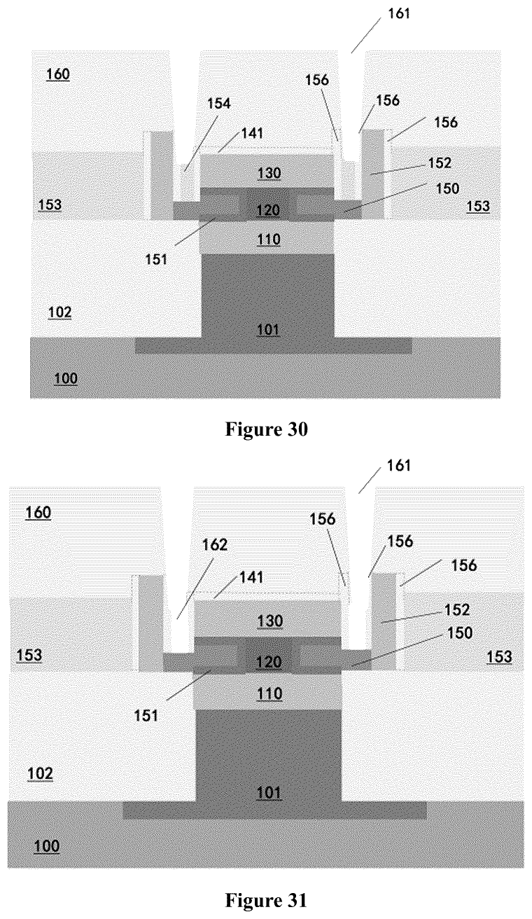

In the first structure, the semiconductor device after forming the first contact hole 161 may be as shown in FIG. 17. FIG. 17 is a cross-sectional view of a semiconductor structure along the line AA. In the second structure, the semiconductor device after forming the first contact hole 161 may be as shown in FIG. 30. FIG. 30 is a cross-sectional view of a semiconductor structure along the line AA.

In an embodiment, after the first contact hole 161 is formed, the sacrificial structure 154 at the bottom of the first contact hole 161 may be removed to form the gap 162 that is located under the first contact hole 161. The gap 162 exposes the gate structure 150 located under the sacrificial structure 154. In a case that the sacrificial structure 154 has a closed shape in the lateral plane, the entire sacrificial structure 154 may be removed, and the formed gap 162 has the closed shape in the lateral direction. In such case, a lateral dimension of the gap 162 is greater than a lateral dimension of the first contact hole 161. In the case that the sacrificial structure 154 has a closed shape in the lateral direction, only a part of the sacrificial structure 154 that is located below the first contact hole 161 may be removed, and the other parts of the sacrificial structure 154 may be retained. Hence, the formed gap 162 is a hollow column. In such case, a lateral dimension of the first contact hole 162 may be either greater than or less than a lateral dimension of the first contact hole 161. The sacrificial structure 154 may be removed through wet etching. The wet etching induces less damage to the gate structure 150 located below the sacrificial structure 154, and hence is beneficial to improving device quality. That is, in comparison with a case that the first contact hole 161 is obtained through dry etching, the wet etching induces less damage to the gate structure 150.

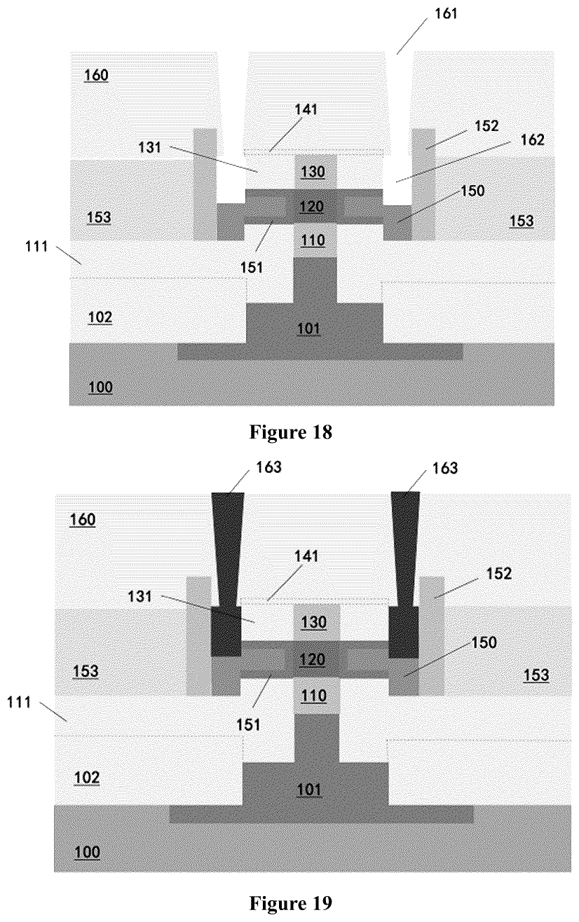

In the first structure, the semiconductor device after removing the sacrificial structure 154 and forming the gap 162 may be as shown in FIG. 18. FIG. 18 is a cross-sectional view of a semiconductor structure along the line AA. In FIG. 18, the lateral dimension of the gap 162 is greater than the lateral dimension of the first contact hole 161. In the second structure, the semiconductor device after removing the sacrificial structure 154 and forming the gap 162 may be as shown in FIG. 31. FIG. 31 is a cross-sectional view of a semiconductor structure along the line AA. In FIG. 31, the lateral dimension of the gap 162 is smaller than the lateral dimension of the first contact hole 161.

In step S106, a first contact structure 163 is formed in the first contact hole 161 and the gap 162. Reference is made to FIGS. 19, 20, 32, and 33.

After the sacrificial structure 154 is removed under the first contact hole 161 and the gap 162 is formed under the first contact hole 161, the first contact structure 163 may be formed in the first contact hole 161 and the gap 162. Since the gap 162 exposes the gate structure 150, the first contact structure 163 formed in the first contact hole 161 and the gap 162 is electrically connected to the gate structure 150. The gate structure 150 may be electrically connected with outside from a top of the capping layer 160, and the first contact structure 163 serves as a contact structure for the gate. A conductor material may be deposited and then etched to obtain the first contact structure 163.

The first contact structure 163 in the gap 162 may be called a fourth portion, and the first contact structure 163 in the first contact hole 161 may be called a fifth portion. That is, the first contact structure 163 may include the fourth portion and the fifth portion which are vertically aligned. The fourth portion is located lower and is in contact with the gate structure 150, and the fifth part is located higher and is in contact with the fourth portion. In a case that the gap 162 has a closed shape in the lateral plane, the fourth portion is of an annular structure in the lateral direction, and a lateral dimension of the fourth portion is greater than the lateral dimension of the fifth portion. In a case that the gap 162 is a hollow column, a lateral dimension of the fourth portion may be either greater than or less than a lateral dimension of the fifth portion.

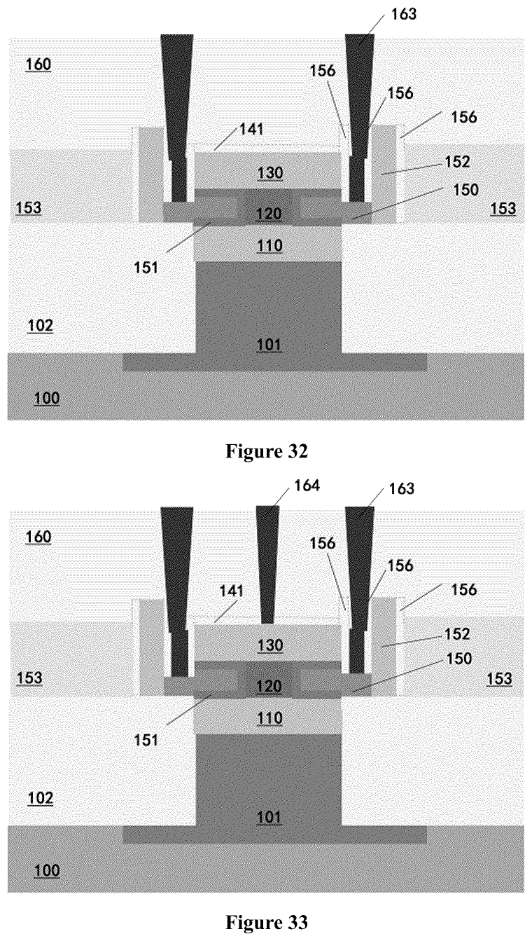

In the first structure, the semiconductor device after forming the first contact structure 163 may be as shown in FIG. 19. FIG. 19 is a cross-sectional view of a semiconductor structure along the line AA. The lateral dimension of the lower portion of the first contact structure 163 is greater than the lateral dimension of the upper portion of the first contact structure 163. In the second structure, the semiconductor device after forming the first contact structure 163 may be as shown in FIG. 32. FIG. 32 is a cross-sectional view of a semiconductor structure along the line AA. The lateral dimension of the lower portion of the first contact structure 163 is smaller than the lateral dimension of the upper portion of the first contact structure 163.

In an embodiment, the capping layer 160 may be etched to obtain a second contact hole reaching the second source-drain layer 130, and a second contact structure 164 is formed in the second contact hole. The second contact structure 164 serves as a contact structure for a drain when the second source-drain layer 130 serves the drain. A conductor material may be deposited and then etched to obtain the second contact structure 164. The first contact structure 163 may be formed either before or after the second contact structure 164 is formed.

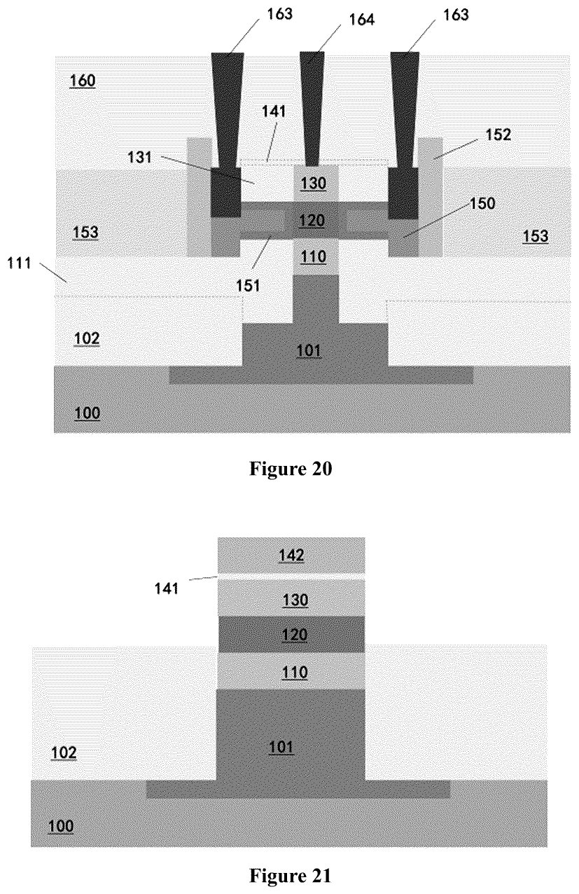

In the first structure, the semiconductor device after forming the second contact structure 164 may be as shown in FIG. 20. FIG. 20 is a cross-sectional view of a semiconductor structure along the line AA. In the second structure, the semiconductor device after forming the second contact structure 164 may be as shown in FIG. 33. FIG. 33 is a cross-sectional view of a semiconductor structure along the line AA.

The method for manufacturing the semiconductor device are provided according to embodiments of the present disclosure. The substrate is provided. The first source-drain layer, the channel layer, and the second source-drain layer are sequentially stacked on the substrate. Both the gate dielectric layer and the gate structure surround the channel layer laterally. The gate structure includes the first portion extending laterally and the second portion extending upward from the periphery of the first portion. The second portion is located at the periphery of the second source-drain layer. The spacer layer is formed at the outer sidewall of the gate structure. The gate structure is etched to reduce a thickness of the gate structure. The sacrificial structure covering the gate structure is formed, and the capping layer covering the second source-drain layer, the sacrificial structure, and the spacer layer is formed. In one embodiment, the sacrificial structure is located at the periphery of the second source-drain layer and enclosed by the spacer layer. The capping layer is etched to obtain the first contact hole reaching the sacrificial structure. The sacrificial structure at the bottom of the first contact hole is removed to form the gap under the first contact hole. The first contact structure is formed in the first contact hole and the gap. When forming the first contact structure, the spacer layer can limit a position of the first contact structure, achieving self-alignment between a bottom of the first contact structure and the gate structure. Hence, contact between the first contact structure and the gate structure has higher quality, and the device has higher reliability.

Based on the method according to embodiments of the present disclosure, a semiconductor device is further provided. Reference is made to FIGS. 22 and 33, each of which is a schematic structural diagram of a semiconductor device according to an embodiment of the present disclosure. As shown in FIGS. 22 and 33, the semiconductor structure includes: a first source-drain layer, a channel layer, a second source-drain layer, a gate dielectric layer, a gate structure, a first contact structure, and a spacer layer.

The first source-drain layer, the channel layer, and the second source-drain layer are stacked on a substrate in the above-listed sequence.

Both the gate dielectric layer and the gate structure surround the channel layer in a lateral in a lateral plane, and the gate structure extends laterally.

The first contact structure is in contact with the gate structure. The first contact structure includes a fourth portion and a fifth portion which are vertically aligned. The fourth portion contacts the gate structure, and the fifth portion contacts the fourth portion. A lateral dimension of the first contact structure is different from a lateral dimension of the fifth portion.

The spacer layer is located at an outer sidewall of the gate structure and an outer sidewall of the fourth portion.

In an embodiment, a first dielectric layer surrounding the first source-drain layer is located at a sidewall of the first source-drain layer, and a second dielectric layer surrounding the second source-drain layer is located at a sidewall of the second source-drain layer. A first recess is formed by a sidewall of the channel layer with respect to the first dielectric layer and the second dielectric layer. The gate dielectric layer and the gate structure are located in the first recess, and the fourth portion is located at a sidewall of the second dielectric layer.

In an embodiment, a second recess is formed by a sidewall of the channel layer with respect to the first source-drain layer and the second source-drain layer. The gate dielectric layer and the gate structure are located in the second recess. The fourth portion is located on a sidewall of the second dielectric layer. A lower surface of the gate structure is higher than an upper surface of the first source-drain layer. An isolation layer is formed between the second source-drain layer and the fourth portion.

The semiconductor device is provided according to the embodiments of the present disclosure. The semiconductor device includes: the first source-drain layer, the channel layer, and the second source-drain layer that are sequentially stacked on the substrate: the gate dielectric layer and the gate structure, both of which surround the channel layer laterally, where the gate structure extends laterally: the first contact structure contacting the gate structure, where the first contact structure includes the fourth portion and the fifth portion which are vertically aligned, the fourth portion contacts the gate structure and the fifth portion contacts the fourth portion, and the lateral dimension of the first contact structure is different from the lateral dimension of the fifth portion: and the spacer layer, located at the outer sidewall of the gate structure and an outer sidewall of the fourth portion. In a process of forming the first contact structure, a position of the first contact structure may be limited by the spacer layer, realizing a self-align of a bottom of the first contact structure and the gate structure, and a contact quality between the first contact structure and the gate structure is improved, reliability of the device is improved, and the precision required for a manufacturing process is reduced.

When elements are illustrated in various embodiments of the present disclosure, the articles “a,” “an”, “the”, and “such” are intended to indicate that a quantity of such element(s) is one or more. The terms “comprise”, “include”, and “have” are all inclusive terms and indicate that there may be an additional element besides listed elements.

The embodiments are described in this specification in a progressive manner. Various embodiments may refer to each other for the same or similar parts, and each embodiment places emphasis on the difference from other embodiments.

The foregoing embodiments are only some embodiments of the present disclosure. The embodiments according to the disclosure are disclosed above, and are not intended to limit the present disclosure. All simple modifications, equivalent variations and improvements made based on the essence of the present disclosure without departing the content of the solutions of the present disclosure fall within the protection scope of the embodiments of the present disclosure.

1. A method for manufacturing a semiconductor device, comprising:
providing a substrate;
providing a first source-drain layer, a channel layer, a second source-drain layer, a gate dielectric layer, and a gate structure, wherein:
the first source-drain layer, the channel layer, and the second source-drain layer are stacked on the substrate in the above-listed sequence,
both the gate dielectric layer and the gate structure surround the channel layer laterally,
the gate structure comprises a first portion extending laterally and a second portion extending upward from a periphery of the first portion, and
the second portion is located at a periphery of the second source-drain layer;
forming a spacer layer at an outer sidewall of the gate structure;
etching the gate structure to reduce a vertical dimension of the gate structure;
forming a sacrificial structure covering the etched gate structure, and forming a capping layer covering the second source-drain layer, the sacrificial structure, and the spacer layer;
etching the capping layer to obtain a first contact hole reaching the sacrificial structure;
removing the sacrificial structure at a bottom of the first contact hole to form a gap under the first contact hole; and
forming a first contact structure in the first contact hole and the gap.

2. The method according to claim 1, wherein providing the first source-drain layer, the channel layer, the second source-drain layer, the gate dielectric layer, and the gate structure comprises:
forming a first dielectric layer surrounding the first source-drain layer at a sidewall of the first source-drain layer, and
forming a second dielectric layer surrounding the second source-drain layer at a sidewall of the second source-drain layer;
forming the gate dielectric layer and the gate structure in a first recess;
wherein the first recess is formed by a sidewall of the channel layer with respect to the first dielectric layer and the second dielectric layer;
wherein the second portion extending upward reaches a sidewall of the second dielectric layer, and the second portion is formed before forming the spacer layer at the outer sidewall of the gate structure.

3. The method according to claim 2, wherein the gate structure further comprises a third portion extending downward and reaching the sidewall of the first dielectric layer.

4. The method according to claim 2, wherein;
before forming the first dielectric layer and forming the second dielectric layer, providing the first source-drain layer, the channel layer, the second source-drain layer, the gate dielectric layer, and the gate structure comprises:
stacking the first source-drain layer, the channel layer, and the second source-drain layer sequentially on the substrate;
patterning the the first source-drain layer, the channel layer, and the second source-drain layer through etching; and
forming the first dielectric layer and forming the second dielectric layer comprises:
etching the channel layer from the sidewall of the channel layer to obtain a third recess, where the third recess is formed by a sidewall of the etched channel layer with respect to the first source-drain layer and the second source-drain layer;
forming a dummy gate structure in the third recess;
etching the first source-drain layer from the sidewall of the first source-drain layer to obtain a fourth recess, wherein the fourth recess is formed by a sidewall of the etched first source-drain layer with respect to the dummy gate structure;
etching the second source-drain layer from the sidewall of the second source-drain layer to obtain a fifth recess, wherein the fifth recess is formed by a sidewall of the etched second source-drain layer with respect to the dummy gate structure;
forming the first dielectric layer in the fourth recess; and
forming the second dielectric layer in the fifth recess.

5. The method according to claim 1, wherein providing the first source-drain layer, the channel layer, the second source-drain layer, the gate dielectric layer, and the gate structure comprises: forming the gate dielectric layer and the gate structure are formed in a second recess, wherein:
the second recess is formed by a sidewall of the channel layer with respect to the first source-drain layer and the second source-drain layer;
the second portion extending upward reaches the sidewall of the second source-drain layer, and the second portion is formed before forming the spacer layer at the outer sidewall of the gate structure;
a lower surface of the gate structure is higher than an upper surface of the first source-drain layer; and
wherein before forming the sacrificial structure covering the gate structure, the method further comprises: forming an isolation layer on the sidewall of the second source-drain layer.

6. The method according to claim 1, further comprising:
etching the capping layer to obtain a second contact hole reaching the second source-drain layer; and
forming a second contact structure in the second contact hole.

7. The method according to claim 1, wherein removing the sacrificial structure at the bottom of the first contact hole comprises:
removing the sacrificial structure at the bottom of the first contact hole through wet etching.

8. A semiconductor device, comprising:
a first source-drain layer, a channel layer, a second source-drain layer, a gate dielectric layer, which are stacked on a substrate in the above-listed sequence;
a gate dielectric layer and a gate structure, both of which surround the channel layer laterally, where the gate structure extends laterally;
a first contact structure contacting the gate structure, wherein the first contact structure comprises a fourth portion and a fifth portion which are vertically aligned, the fourth portion contacts the gate structure and the fifth portion contacts the fourth portion, and a lateral dimension of the first contact structure is different from a lateral dimension of the fifth portion; and
a spacer layer, located at an outer sidewall of the gate structure and an outer sidewall of the fourth portion.

9. The semiconductor device according to claim 8, further comprising:
a first dielectric layer surrounding the first source-drain layer, wherein the first dielectric layer is located at a sidewall of the first source-drain layer;
a second dielectric layer surrounding the second source-drain layer, wherein the first dielectric layer is located at a sidewall of the second source-drain layer; wherein:
a first recess is formed by a sidewall of the channel layer with respect to the first dielectric layer and the second dielectric layer;
the gate dielectric layer and the gate structure are located in the first recess; and
the fourth portion is located at a sidewall of the second dielectric layer.

10. The semiconductor device according to claim 8, wherein:
a second recess is formed by a sidewall of the channel layer with respect to the first source-drain layer and the second source-drain layer;
the gate dielectric layer and the gate structure are located in the second recess;
a lower surface of the gate structure is higher than an upper surface of the first source-drain layer; and
an isolation layer is formed between the second source-drain layer and the fourth portion.

11. The method according to claim 2, further comprising:
etching the capping layer to obtain a second contact hole reaching the second source-drain layer; and
forming a second contact structure in the second contact hole.

12. The method according to claim 3, further comprising:
etching the capping layer to obtain a second contact hole reaching the second source-drain layer; and
forming a second contact structure in the second contact hole.

13. The method according to claim 4, further comprising:
etching the capping layer to obtain a second contact hole reaching the second source-drain layer; and
forming a second contact structure in the second contact hole.

14. The method according to claim 5, further comprising:
etching the capping layer to obtain a second contact hole reaching the second source-drain layer; and
forming a second contact structure in the second contact hole.
